(19) United States
(12) Patent Application Publication
(10) Pub. No.: US 2025/0385024 A1
(43) Pub. Date: Dec. 18, 2025

(54) WIRE HOLDING STRUCTURE AND ELECTRONIC DEVICE

(71) Applicant: NIDEC PRECISION CORPORATION, Tokyo (JP)

(72) Inventor: Yukihiro MATSUMOTO, Tokyo (JP)

(21) Appl. No.: 18/875,166

(22) PCT Filed: Apr. 11, 2023
(86) PCT No.: PCT/JP2023/014649

§ 371 Date: Dec. 16, 2024

(30) Foreign Application Priority Data
Jun. 28, 2022 (JP) 2022-103187

(51) Int. Cl. H01B 7/40; G03B 17/02

(52) U.S. Cl. CPC H01B 7/40; G03B 17/02

(57) ABSTRACT

A wire holding structure is simple and allows a wire to be routed without interfering with movement of a movable member. The wire holding structure includes wires extending across a prism lever and a wire holder holding the wires. The wire holder includes a base spaced apart from, in the positive Z-direction, an area in which the prism lever is movable, and a pair of holding pieces spaced apart from the base in the Z-direction and extending oppositely to each other in the Y-direction. The holding pieces are elastically deformable. The wire holder has, between the holding pieces and the base, a wire housing space housing the wires. The wire holder has, between the holding pieces, a wire insertion slit having a minimum width smaller than the smallest outer diameter of the wires.

### RELATED APPLICATIONS

The present application is National stage of application No. PCT/JP2023/014649, filed on Apr. 11, 2023, and claims priority based on Japanese Patent Application No. 2022-103187, filed Jun. 28, 2022.

### FIELD

The present invention relates to a wire holding structure and an electronic device, and particularly to a structure for fastening a wire near a movable member.

### BACKGROUND

Electronic devices include various wires routed as appropriate for the voltage and the types of signals. For an electronic device including a movable member, the wires are not to interfere with movement of the movable member. To allow a wire to be routed near the movable member, a known structure includes a bridge member for bridging the wire near the movable member. The wire is fastened to the bridge member not to interfere with movement of the movable member (refer to, for example, Patent Literature 1). Recent electronic devices are to be compact and to include fewer components. A method for routing a wire near a movable member without such a bridge member is thus awaited.

### CITATION LIST

### Patent Literature

Patent Literature 1: Japanese Registered Utility Model No. 3098046

### BRIEF SUMMARY

### Technical Problem

In response to the above issue, one or more aspects of the present invention are directed to a wire holding structure that is simple and allows a wire to be routed without interfering with movement of a movable member and an electronic device with the wire holding structure.

### Solution to Problem

A wire holding structure according to a first aspect of the present invention is simple and allows a wire to be routed without interfering with movement of a movable member. The wire holding structure includes at least one wire extending across a movable member. The at least one wire includes a first portion and a second portion closer to the movable member than the first portion. The wire holding structure further includes a wire holder holding a portion of the at least one wire between the first portion and the second portion. The wire holder includes a base spaced apart from, in a first direction, an area in which the movable member is movable, and a pair of holding pieces spaced apart from the base in the first direction and extending oppositely to each other in a second direction perpendicular to the first direction. At least one of the pair of holding pieces is elastically deformable. The wire holder has, between the pair of holding pieces and the base, a wire housing space housing the at least one wire. The wire holder has, between the pair of holding pieces, a wire insertion slit having a minimum width smaller than a smallest outer diameter of the at least one wire.

An electronic device according to a second aspect of the present invention has the wire holding structure described above.

### BRIEF DESCRIPTION OF DRAWINGS

FIG. 1 is a perspective view of some of the components of a camera as an electronic device according to a first embodiment of the present invention.

FIG. 2 is an enlarged perspective view of a portion near a wire holder in a gear unit in the camera shown in FIG. 1.

FIG. 3 is a plan view of the portion near the wire holder in the gear unit shown in FIG. 2, also showing a wire.

FIG. 4 is an enlarged front view of the portion near the wire holder in the gear unit shown in FIG. 2.

FIG. 5 is an enlarged perspective view of a portion near a wire holder in a gear unit in a second embodiment of the present invention.

FIG. 6 is an enlarged perspective view of a portion near a wire holder in a gear unit in a third embodiment of the present invention.

### DETAILED DESCRIPTION

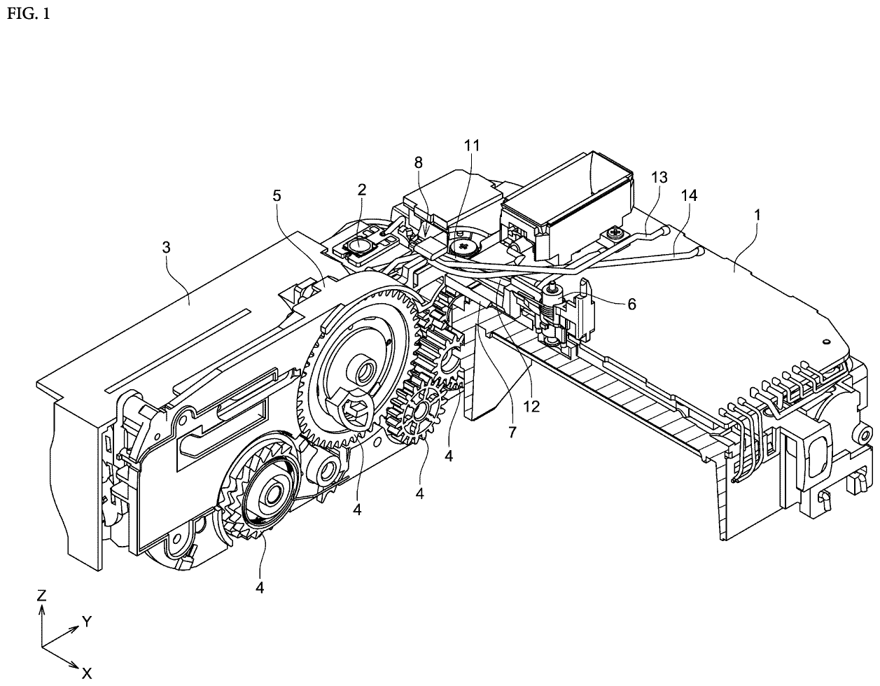

A wire holding structure and an electronic device with the wire holding structure according to one or more embodiments of the present invention will now be described in detail with reference to FIGS. 1 to 6. In FIGS. 1 to 6, like reference numerals denote like or corresponding components. Such components will not be described repeatedly. In FIGS. 1 to 6, the scale and dimensions of each component may be exaggerated, or one or more components may not be shown. Unless otherwise specified, the terms such as first and second will be used simply to distinguish the components and will not represent a specific order or sequence.

FIG. 1 is a perspective view of some components of a camera as an electronic device according to a first embodiment of the present invention. Although the electronic device according to the present embodiment is a camera, this is a mere example. The wire holding structure according to one or more embodiments of the present invention may be used in an electronic device in which a wire is to be routed near a movable member. For ease of explanation in the present embodiment, up or upward refers to the positive Z-direction in FIG. 1, and down or downward refers to the negative Z-direction.

As shown in FIG. 1, the camera includes a circuit board 1 on which various electronic components are mounted, a frame 3 to which a motor and a switch 2 are attached, a gear unit 5 to which multiple gears 4 drivable by the motor are attached, and a prism lever 7 that rotates about a shaft 6 to move a prism (not shown) for a viewfinder. The camera also includes four wires 11 to 14 connected to an electrical circuit on the circuit board 1. The wires 11 to 14 extend across the prism lever 7, which is a movable member, and are held near the prism lever 7 by a wire holder 8 included in the gear unit 5. In the present embodiment, the wires 11 to 14 and the wire holder 8 holding the wires 11 to 14 are included in the wire holding structure according to one or more embodiments of the present invention.

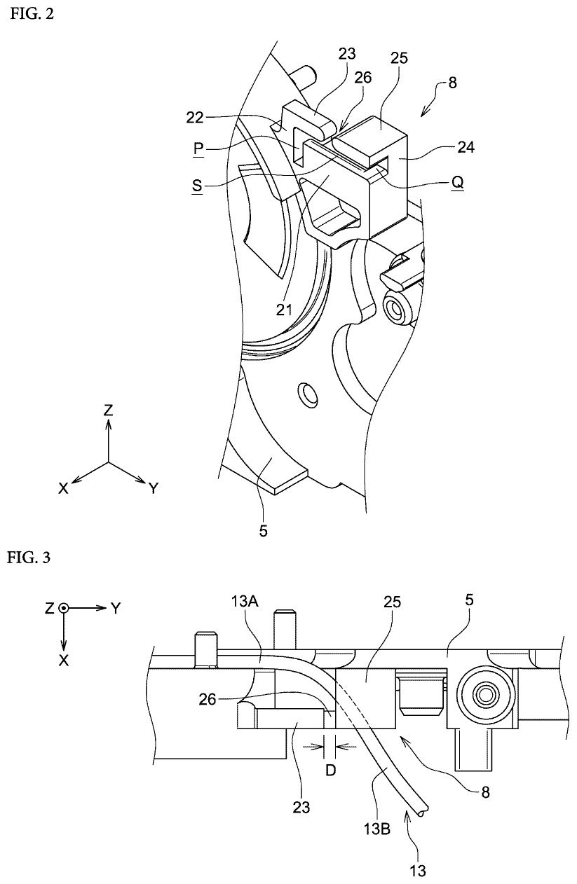

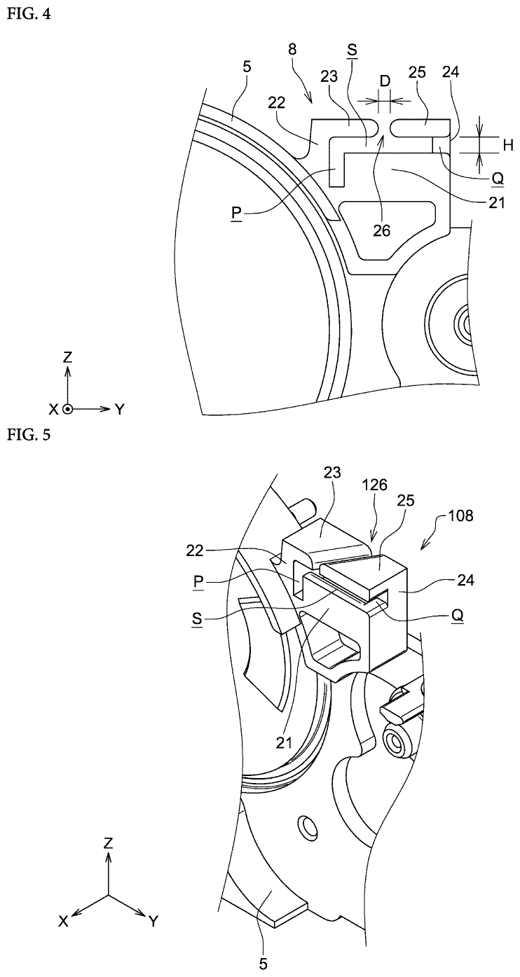

FIG. 2 is an enlarged perspective view of a portion near the wire holder 8 in the gear unit 5. FIG. 3 is a plan view of the portion near the wire holder 8, also showing the wire 13. FIG. 4 is an enlarged front view of the portion near the wire holder 8. As shown in FIGS. 2 to 4, the wire holder 8 includes a base 21 extending in the positive Z-direction, a first arm 22 extending in the positive Z-direction near the base 21, a first holding piece 23 extending in the positive Y-direction from an end of the first arm 22 in the positive Z-direction, a second arm 24 extending in the positive Z-direction near the base 21, and a second holding piece 25 extending in the negative Y-direction from an end of the second arm 24 in the positive Z-direction.

Although the prism lever 7 rotates about the shaft 6 as described above, the base 21 in the wire holder 8 is spaced apart from, in the positive Z-direction, an area in which the prism lever 7 is rotatable (an area in which the prism lever 7 is movable). The first holding piece 23 and the second holding piece 25 are each spaced apart from the upper end of the base 21, defining a wire housing space S extending in the Y-direction between the first holding piece 23 and the base 21 and between the second holding piece 25 and the base 21. The wire housing space S houses the wires 11 to 14.

The first holding piece 23 has its end in the positive Y-direction facing an end of the second holding piece 25 in the negative Y-direction with a wire insertion slit 26 between these ends. The wire insertion slit 26 has a width D (refer to FIGS. 3 and 4) in the Y-direction smaller than the smallest outer diameter of the wires 11 to 14 housed in the wire housing space S. The smallest outer diameter of one or more wires herein refers to the outer diameter of a single wire housed in the wire housing space S or the smallest outer diameter of the outer diameters of multiple wires housed in the wire housing space S.

For ease of understanding, the wire 13 alone is shown in FIG. 3. Although the wire 13 is described below as a typical example, the other wires 11, 12, and 14 have the same structure as the wire 13. The wire 13 includes a portion 13A (first portion) and a portion 13B (second portion) closer to the prism lever 7 than the portion 13A. The portion 13A is located along a side surface of the gear unit 5. The portion 13B is bent in the positive X-direction to be connected to the circuit board 1 (refer to FIG. 1). The wire holder 8 holds a portion of the wire 13 between the first portion 13A and the second portion 13B. The wire insertion slit 26 in the wire holder 8 in the present embodiment extends in the X-direction to intersect with the wire 13 extending obliquely as described above.

To allow the wires 11 to 14 to be moved in the Y-direction (second direction) in the wire housing space S, the wire housing space S in the wire holder 8 may have a width H (refer to FIG. 4) in the Z-direction (first direction) larger than or equal to the smallest outer diameter of the wires 11 to 14. The wire housing space S may have the width H smaller than twice the smallest outer diameter of the wires 11 to 14. The wire housing space S having the width H smaller than twice the smallest outer diameter of the wires 11 to 14 prevents the wires 11 to 14 from being interchanged with each other in the Y-direction. This allows the wires 11 to 14 to be easily aligned in the wire housing space S in the wire holder 8.

In the present embodiment, the wire holder 8 has a cutout P in the negative Y-direction from the base 21. The first arm 22 supporting the first holding piece 23 thus extends in the Z-direction. In the present embodiment, the first holding piece 23 and the second holding piece 25 are both elastically deformable. The first arm 22 supporting the first holding piece 23 has an extended length in the Z-direction and is thus more elastic. This causes the first holding piece 23 to elastically deform more easily than the second holding piece 25.

In the wire holder 8 with the above structure, the holding pieces 23 and 25 (in particular, the holding piece 23) elastically deform when each of the wires 11 to 14 is press-fitted into the wire insertion slit 26 between the holding piece 23 and the holding piece 25. This allows the wires 11 to 14 to pass through the wire insertion slit 26 and be inserted into the wire housing space S. The wire insertion slit 26 has the width D smaller than the smallest outer diameter of the wires 11 to 14. This prevents the wires in the wire housing space S from coming out of the wire housing space S unless the holding piece 23 or 25 deforms unintendedly. The wire housing space S has the width H larger than or equal to the smallest outer diameter of the wires 11 to 14 and smaller than twice the smallest outer diameter. This allows the wires 11 to 14 to be aligned in the wire housing space S and also to be moved in the Y-direction easily.

In the present embodiment, a connection space Q is defined in the positive Y-direction from the wire housing space S as shown in FIG. 4. When the wires 11 to 14 are routed to the circuit board 1 located in the positive Y-direction from the wire holder 8, wires (the wires 11 and 12) located in the positive Y-direction can be routed through the connection space Q. This allows the wires 11 to 14 to be routed more freely.

In a known structure, a wire fastened to a bridge member may not be moved flexibly, and then may not be easily soldered to a circuit board. However, in the wire holding structure according to the present embodiment, the wires 11 to 14 held by the wire holder 8 can be moved relatively freely in the wire housing space S, and can then be easily soldered to the circuit board 1.

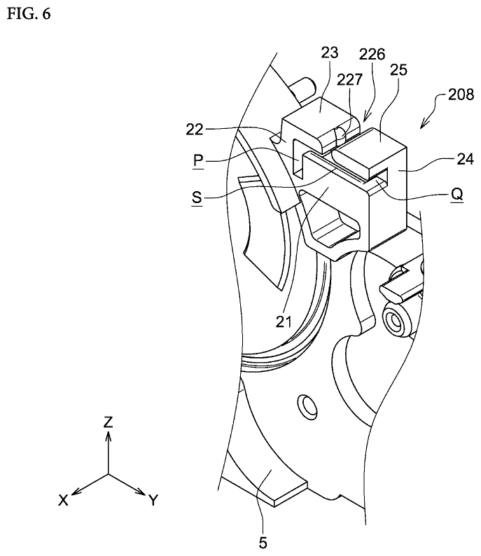

FIG. 5 is an enlarged perspective view of a portion near a wire holder 108 in the gear unit 5 in a second embodiment of the present invention. The wire holder 108 has, between the first holding piece 23 and the second holding piece 25, a wire insertion slit 126 extending in a direction substantially perpendicular to a direction in which the wires 11 to 14 extend. The wire insertion slit 126 extending in the direction substantially perpendicular to the direction in which the wires 11 to 14 extend allows the wires 11 to 14 housed in the wire housing space S to be less easily aligned in the direction in which the wire insertion slit 126 extends. This further reduces the likelihood that the wires 11 to 14 in the wire housing space S slip off the wire holder 8.

FIG. 6 is an enlarged perspective view of a portion near a wire holder 208 in the gear unit 5 in a third embodiment of the present invention. The wire holder 208 has a wire insertion slit 226 extending in the X-direction between the first holding piece 23 and the second holding piece 25. The first holding piece 23 includes a protrusion 227 protruding toward the second holding piece 25 facing the first holding piece 23. In this case, the wire insertion slit 226 has a minimum width equal to the width between the top of the protrusion 227 in the first holding piece 23 and the second holding piece 25 facing the protrusion 227. The minimum width is smaller than the smallest outer diameter of the wires 11 to 14.

In the above structure including the protrusion 227 described above, the wires 11 to 14 being inserted into the wire housing space S simply receive resistance resulting from contact with the protrusion 227, and are thus inserted into the wire housing space S easily. To reduce damage or resistance to the wires 11 to 14, the protrusion 227 may have, for example, a curved surface such as a spherical surface.

As described above, the wire holding structure according to the first aspect of the present invention is simple and allows a wire to be routed without interfering with movement of a movable member. More specifically, the wire holding structure according to one or more embodiments of the present invention may be any of the structures described below.

### First Structure

A wire holding structure includes at least one wire extending across a movable member. The at least one wire includes a first portion and a second portion closer to the movable member than the first portion. The wire holding structure further includes a wire holder holding a portion of the at least one wire between the first portion and the second portion. The wire holder includes a base spaced apart from, in a first direction, an area in which the movable member is movable, and a pair of holding pieces spaced apart from the base in the first direction and extending oppositely to each other in a second direction perpendicular to the first direction. At least one of the pair of holding pieces is elastically deformable. The wire holder has, between the pair of holding pieces and the base, a wire housing space housing the at least one wire. The wire holder has, between the pair of holding pieces, a wire insertion slit having a minimum width smaller than a smallest outer diameter of the at least one wire.

In this structure, the holding pieces elastically deform to allow the wire to be inserted into the wire housing space through the wire insertion slit. The wire then does not come out of the wire housing space unless any of the holding pieces deforms unintendedly. The wire can thus be held between the pair of holding pieces and the base of the wire holder spaced apart from the area in which the movable member is movable. This allows the wire to be routed without interfering with movement of the movable member. The wire holding structure can thus be compact and include fewer components.

### Second Structure

In the first structure, the wire housing space between the pair of holding pieces and the base may have a width in the first direction larger than or equal to the smallest outer diameter of the at least one wire and smaller than twice the smallest outer diameter. The wire housing space having the width in the above range allows the wire to be aligned in the wire housing space and also to be easily moved in the wire housing space.

### Third Structure

In the first or second structure, the wire insertion slit may have the minimum width set to allow the at least one wire being press-fitted to pass through the wire insertion slit.

### Fourth Structure

In any one of the first to third structures, the at least one of the pair of holding pieces may be connected to an arm extending in the first direction at a position spaced apart from the base in the second direction. The arm can be more elastic, thus causing the holding pieces to elastically deform easily.

### Fifth Structure

In any one of the first to fourth structures, the wire insertion slit may extend in a direction intersecting with the at least one wire held by the wire holder. This structure allows the wire housed in the wire housing space to be less easily aligned in the direction in which the wire insertion slit extends, thus reducing the likelihood that the wire in the wire housing space slips off the wire holder.

### Sixth Structure

In the fifth structure, the wire insertion slit may extend in a direction perpendicular to a direction in which the at least one wire held by the wire holder extends. This structure allows the wire housed in the wire housing space to be far less easily aligned in the direction in which the wire insertion slit extends, thus further reducing the likelihood that the wire in the wire housing space slips off the wire holder.

### Seventh Structure

In any one of the first to sixth structures, at least one of the pair of holding pieces may include a protrusion protruding toward the other of the holding pieces facing the at least one of the pair of holding pieces. In this structure including the protrusion, the wire being inserted into the wire housing space simply receives resistance resulting from contact with the protrusion, and is thus inserted into the wire housing space easily.

### Eighth Structure

In the seventh structure, the protrusion may have a curved surface to reduce damage or resistance to the wire.

An electronic device according to a second aspect of the present invention has the wire holding structure described above.

Although the embodiments of the present invention have been described above, the present invention is not limited to the above embodiments and may be modified variously within the scope of its technical idea.

This application claims priority to Japanese Patent Application No. 2022-103187 filed on Jun. 28, 2022, the entire disclosure of which is incorporated herein by reference.

### INDUSTRIAL APPLICABILITY

The structure according to one or more embodiments of the present invention may be used to fasten a wire near a movable member.

1. A wire holding structure, comprising:
at least one wire extending across a movable member, the at least one wire including a first portion and a second portion, the second portion being closer to the movable member than the first portion; and
a wire holder holding a portion of the at least one wire between the first portion and the second portion, the wire holder including
a base spaced apart from, in a first direction, an area in which the movable member is movable, and
a pair of holding pieces spaced apart from the base in the first direction and extending oppositely to each other in a second direction perpendicular to the first direction, at least one of the pair of holding pieces being elastically deformable,
the wire holder having a wire housing space between the pair of holding pieces and the base, the wire housing space housing the at least one wire,
the wire holder having a wire insertion slit between the pair of holding pieces, the wire insertion slit having a minimum width smaller than a smallest outer diameter of the at least one wire.

2. The wire holding structure according to claim 1, wherein
the wire housing space between the pair of holding pieces and the base has a width in the first direction larger than or equal to the smallest outer diameter of the at least one wire and smaller than twice the smallest outer diameter.

3. The wire holding structure according to claim 1, wherein
the wire insertion slit has the minimum width set to allow the at least one wire being press-fitted to pass through the wire insertion slit.

4. The wire holding structure according to claim 1, wherein
the at least one of the pair of holding pieces is connected to an arm extending in the first direction at a position spaced apart from the base in the second direction.

5. The wire holding structure according to claim 1, wherein
the wire insertion slit extends in a direction intersecting with the at least one wire held by the wire holder.

6. The wire holding structure according to claim 5, wherein
the wire insertion slit extends in a direction perpendicular to a direction in which the at least one wire held by the wire holder extends.

7. The wire holding structure according to claim 1, wherein
at least one of the pair of holding pieces includes a protrusion protruding toward the other of the holding pieces facing the at least one of the pair of holding pieces.

8. The wire holding structure according to claim 7, wherein
the protrusion has a curved surface.

9. An electronic device, comprising:
the wire holding structure according to claim 1.
